(19) United States
(12) Patent Application Publication
(10) Pub. No.: US 2006/0001110 A1
(43) Pub. Date: Jan. 5, 2006

(54) Lateral trench MOSFET

(76) Inventor: Atsushi Igarashi, Chiba-shi (JP)

Correspondence Address: BRUCE L. ADAMS, ESQ., 50 BROADWAY -31ST FLOOR, NEW YORK, NY, 10004, US

(21) Appl. No.: 11/166,973

(22) Filed: Jun. 24, 2005

(30) Foreign Application Priority Data
Jul. 1, 2004 (JP) 2004-195888

(51) Int. Cl. H01L 29/76; H01L 21/336

(52) U.S. Cl. 257/401; 438/284

(57) ABSTRACT

In a lateral trench MOSFET in which a channel width is increased while an element area is not increased to attain reduction in an ON resistance, a source layer (004) and a drain layer (005) are formed in the vicinity of both ends of a trench (008) through multi-directional ion implantation. With this structure, each the source layer (004) and the drain layer (005) are formed deeper than the trench (008), electrons flow through the entire channel region, and an effective channel length becomes shorter. Further reduction of the ON resistance can be realized.

### BACKGROUND OF THE INVENTION

1. Field of the Invention

The present invention relates to a semiconductor device whose ON resistance is low, and more particularly to a semiconductor device provided with a lateral MOSFET.

2. Description of the Related Art

A lateral MOSFET has been used as a semiconductor switching-device at low voltage. High driving capability is required when a lateral MOSFET is used to switch large current. Reduction of ON resistance is important to improve driving capability. Since resistance of the channel occupies most of the ON resistance of a lateral MOSFET, it is sufficient to increase channel width in order to reduce the ON resistance.

Planer area (hereinafter, referred to as element area) of the lateral MOSFET, however, increases, as the channel width increases. In a conventional lateral trench MOSFET as shown in FIGS. 2A to 2C, plural trenches (grooves) 008 are formed on a substrate surface between a source layer 004 and a drain layer 005 so as to be parallel to gate length direction, and a gate electrode 003 is formed in each of the trenches 008 through a gate insulating film (oxide film) 006, whereby the channel width is increased with the same element area (for example, refer to JP 3405681 B). FIG. 2A is a plan view of the lateral trench MOSFET, FIG. 2B is a sectional view taken along a line 2A-2A′ in FIG. 2A, and FIG. 2C.is a sectional view taken along a line 2B-2B′ in FIG. 2A.

In prior art, forming the trenches can increase the channel width of the lateral trench MOSFET. However, in the conventional lateral trench MOSFET, the depths of the source layer and the drain layer are shallow with respect to the depth of the trench. As shown in FIG. 2B, the distance between the source layer 004 and the drain layer 005 is thus long along the channel at the bottom surface of the trench 008 so that current hardly flows. Current accumulates to the surface and a part of the side surface of the trench 008. As a result, the channel formed in the vicinity of the bottom of the trench 008 does not contribute to the increase of the channel width. Contact area between the channel and the source and drain layers in the MOSFET is not extended, and thus, the ON resistance is not sufficiently reduced. Further, it is considerable that the accumulation of the current to one point causes heat generation, which further deteriorates the current flow. A method of expanding the flow of electrons through the formation of a buried layer etc. may be given in order to effectively use the entire channel, but this method comes with a problem of the increase of the number of manufacturing steps.

### SUMMARY OF THE INVENTION

It is an object of the present invention to provide a semiconductor device to solve the problems described above.

That is, the present invention provides:

A semiconductor device, including: a first conductivity type semiconductor layer formed on a surface of a semiconductor substrate; trenches formed in parallel from a surface of the first conductivity type semiconductor layer to its midway in depth; a gate electrode provided through a gate oxide film which is formed on a surface portion of the trench except the vicinities of both end portions thereof and on the surface portion of the first conductivity type semiconductor layer; and a second conductivity type semiconductor layer formed at a position lower than that of a bottom surface of the trench through ion implantation of second conductivity type impurities to the surface of the first conductivity type semiconductor layer and to the inside of the trench with the gate electrode as a mask.

According to the present invention, the semiconductor device including the lateral MOSFET, which has a large connection area between the channel formed in the trench and the source and drain layers and which has a small ON resistance, can be realized without increasing the element area or the number of steps.

### BRIEF DESCRIPTION OF THE DRAWINGS

In the accompanying drawings:

FIGS. 1A to 1D are a plan view of a basic structure of the present invention, a sectional view taken along a line 1A-1A′ in FIG. 1A, a sectional view taken along a line 1B-1B′ in FIG. 1A, and a sectional view taken along a line 1C-1C′ in FIG. 1A, respectively;

FIGS. 2A to 2C are a plan view of a basic structure in the prior art, a sectional view taken along a line 2A-2A′ in FIG. 2A, and a sectional view taken along a line 2B-2B′ in FIG. 2A, respectively;

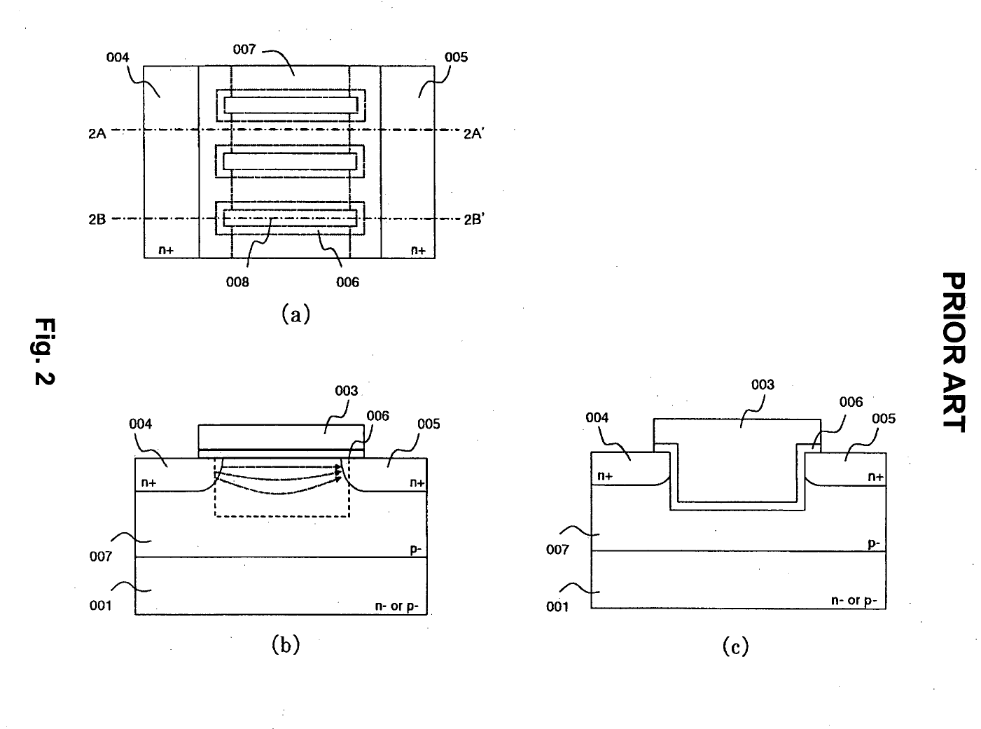

FIGS. 3A to 3C are a plan view of the present invention including an offset structure, a sectional view taken along a line 3A-3A′ in FIG. 3A, and a sectional view taken along a line 3B-3B′ in FIG. 3A, respectively;

FIGS. 4A to 4C are a plan view of the present invention including a DDD structure, a sectional view taken along a line 4A-4A′ in FIG. 4A, and a sectional view taken along a line 4B-4B′ in FIG. 4A, respectively; and

FIGS. 5Ato 5C are a plan view of the present invention including an LDMOS structure, a sectional view taken along a line 5A-5A′ in FIG. 5A, and a sectional view taken along a line 5B-5B′ in FIG. 5A, respectively.

### DETAILED DESCRIPTION OF THE PREFERRED EMBODIMENTS

Hereinafter, the best modes for implementing the present invention will be described with the following embodiments.

Embodiment 1

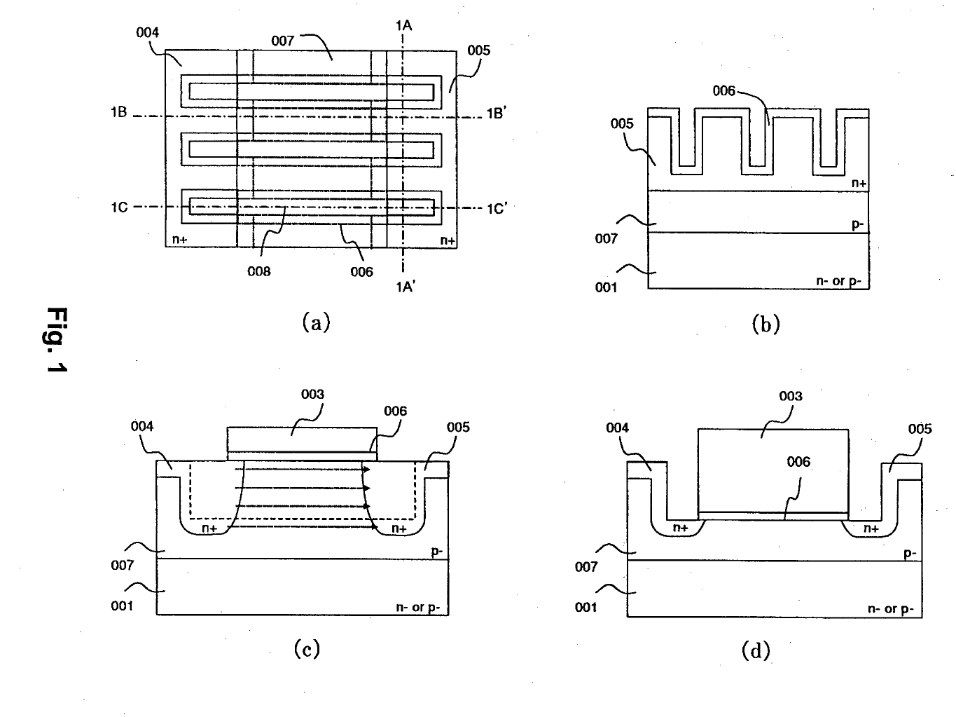

FIGS. 1A to 1D show Embodiment 1 according to the present invention. FIG. 1A is a plan view, FIG. 1B is a sectional view taken along a line 1A-1A′ in FIG. 1A, FIG. 1C is a sectional view taken along a line 1B-1B′ in FIG. 1A, and FIG. 1D is a sectional view taken along a line 1C-1C′ in FIG. 1A. In this lateral trench MOSFET, a first conductivity type semiconductor layer, for example, a P-type well layer 007 is formed on a high resistance semiconductor substrate 001. Here, the well layer 007 can be omitted by setting an impurity concentration of the semiconductor substrate 001 equal to that of the well layer.

Plural parallel trenches 008 are formed in the P-type well layer 007 as to reach a point midway in its depth. A gate electrode 003 is formed, through an oxide film 006, on a surface portion of the trench 008 except for the vicinities of both end portions thereof. With the gate electrode 003 as a mask, ion implantation is performed through spinning while holding a certain angle respect to a vertical direction to the wafer, whereby impurities of a second conductivity type, for example, N type are implanted to the surface of the P-type well layer 007 and to side surfaces and bottom surfaces inside the trench 008 to form a source layer 004 and a drain layer 005 as shown in FIG. 1B. Since the source layer 004 and the drain layer 005 are formed deeper than the trench 008, electrons flow through the entire channel region as shown in FIG. 1C so that the channel can be used effectively. Further reduction of the ON resistance can be realized. Moreover, an effective channel length can be uniformly shortened, and this also leads to the reduction of the ON resistance.

Embodiment 2

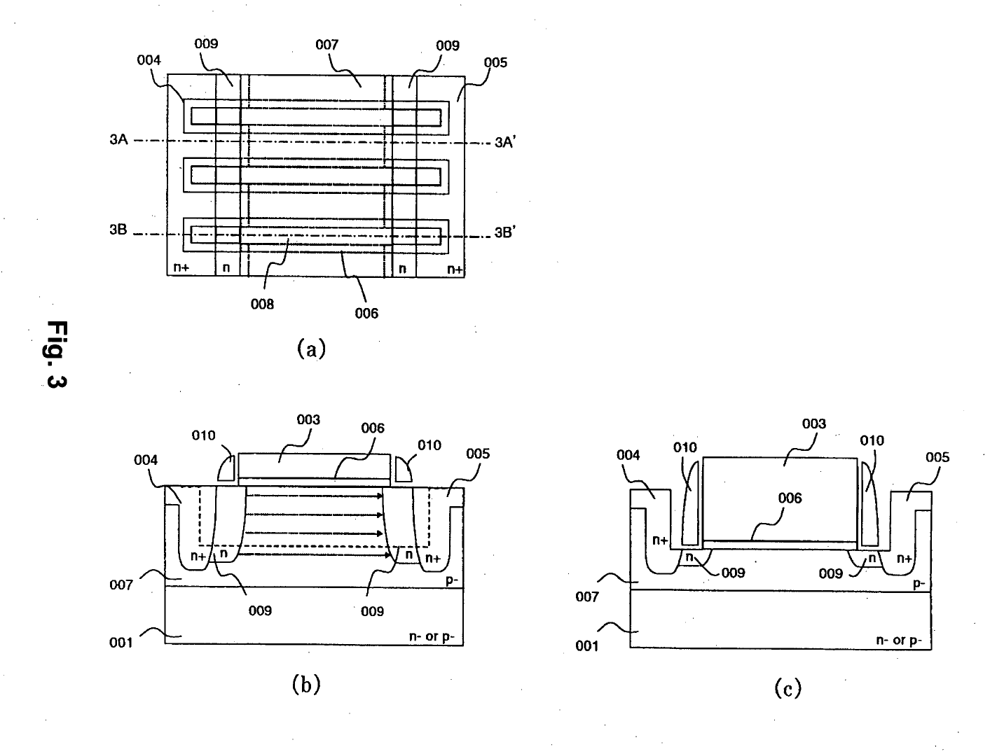

FIGS. 3A to 3C show Embodiment 2. FIG. 3A is a plan view, FIG. 3B is a sectional view taken along a line 3A-3A′ in FIG. 3A, and FIG. 3C is a sectional view taken along a line 3B-3B′ in FIG. 3A. This embodiment is a modified structure of Embodiment 1. As shown in FIGS. 3B and 3C, second conductivity type offset layers 009 are formed by using so-calledsidewalls010. With such an offset structure, a higher withstand voltage can be attained in addition to the effects brought by Embodiment 1.

Embodiment 3

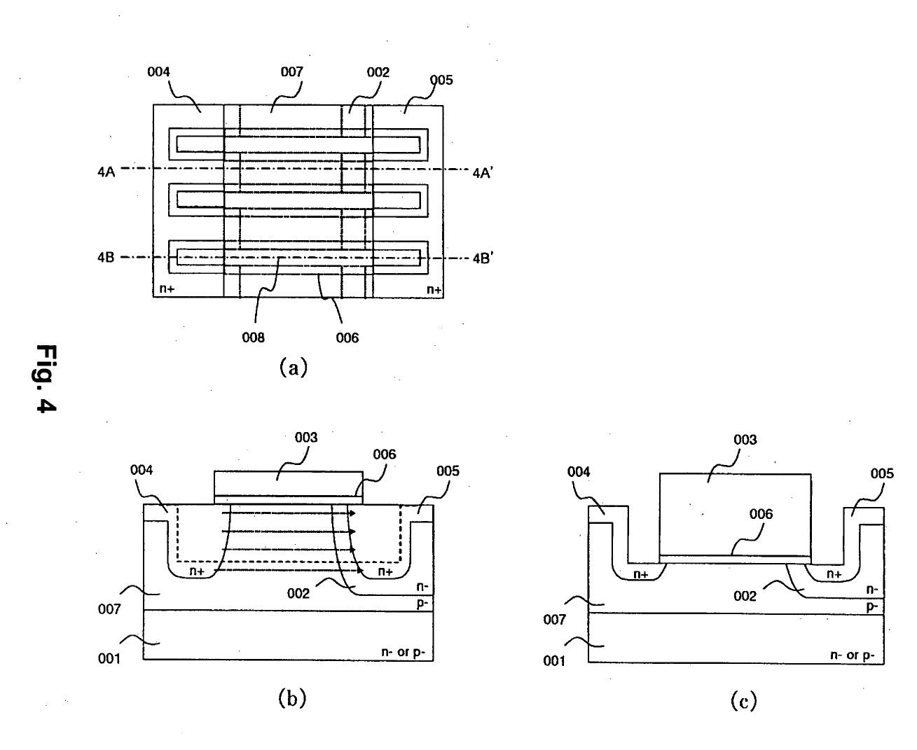

FIGS. 4A to 4C show Embodiment 3. FIG. 4A is a plan view, FIG. 4B is a sectional view taken along a line 4A-4A′ in FIG. 4A, and FIG. 4C is a sectional view taken along a line 4B-4B′ in FIG. 4A. This embodiment is a modified structure of Embodiment 1, and includes what is called a DDD (Double Diffused Drain) structure. As shown in FIGS. 4B and 4C, ion implantation is performed only from the drain side and by thermal diffusion a second conductivity type high resistance layer 002 is formed on the drain side. Then ion implantation is performed to both sides to form the source layer 004 and the drain layer 005. This structure can attain a higher withstand voltage in addition to the effects brought by Embodiment 1.

Embodiment 4

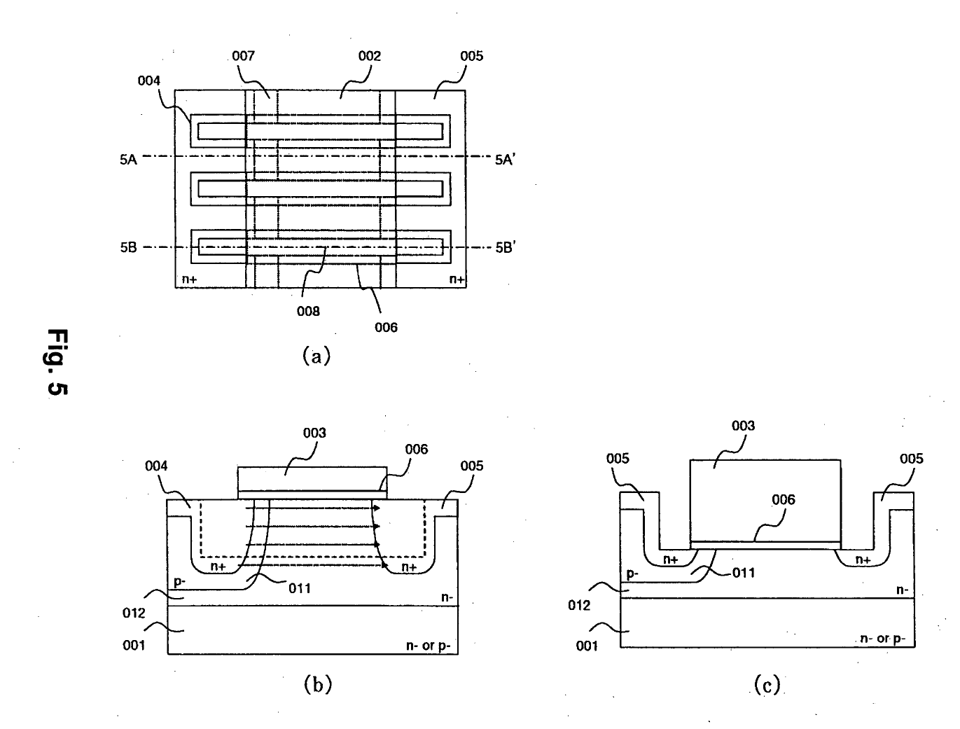

FIGS. SA to 5C show Embodiment 4. FIG. 5A is a plan view, FIG. 5B is a sectional view taken along a line 5A-5A′ in FIG. 5A, and FIG. 5C is a sectional view taken along a line 5B-5B′ in FIG. 5A. This embodiment is a modified structure of Embodiment 1, and includes what is called an LDMOS (Lateral Double Diffused MOS) structure. As shown in FIGS. 5B and 5C, an N-type well layer 012 is formed on the semiconductor substrate instead of the P-type well layer 007 in Embodiment 1. After the formation of the trenches 008 and before the formation of the source layer 004 and the drain layer 005, ion implantation is performed only from the source side, and bythermal diffusiona first conductivitytype highresistance layer 011 for a channel of the transistor is formed. Such a structure can attain a higher withstand voltage in addition to the effects brought by Embodiment 1.

Note that, in Embodiment 4, it is clear that the N-type well layer 012 is not necessarily required in using a second conductivity type semiconductor substrate.

What is claimed is:

1. A semiconductor device, comprising:
a first conductivity type semiconductor layer disposed on a surface of a semiconductor substrate;
trenches disposed in parallel from a surface of the first conductivity type semiconductor layer to a point midway in its depth;
a gate electrode provided through a gate oxide film which is disposed on a surface portion of each trench except for vicinities of both end portions thereof and on the surface portion of the first conductivity type semiconductor layer; and
a second conductivity type source layer and a second conductivity type drain layer each disposed at a position lower than that of a bottom surface of the trench, to the surface of the first conductivity type semiconductor layer, and to the inside of the trench with the gate electrode as a mask.

2. A semiconductor device according to claim 1, further comprising an offset structure.

3. A semiconductor device according to claim 1, further comprising a DDD structure.

4. A semiconductor device according to claim 1, further comprising an LDMOS structure.

5. A semiconductor device according to claim 1, wherein the second conductivity type source layer and the second conductivity type drain layer are disposed through ion implantation of second conductivity type impurities
